(19) United States
(12) Patent Application Publication
(10) Pub. No.: US 2022/0085792 A1
(43) Pub. Date: Mar. 17, 2022

(54) INTEGRATION STRUCTURE OF CRYSTAL OSCILIATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Zhejiang (CN)

(21) Appl. No.: 17/419,681

(22) PCT Filed: Nov. 5, 2019
(86) PCT No.: PCT/CN2019/115657

§ 371 Date: Jun. 29, 2021

(30) Foreign Application Priority Data
Dec. 29, 2018 (CN) 201811647886.3

(51) Int. Cl. H03H 9/205; H03H 3/02; H03H 9/19; H01L 27/20

(52) U.S. Cl. CPC H03H 9/205; H01L 27/20; H03H 9/19; H03H 3/02

(57) ABSTRACT

A structure and method for integrating a crystal resonator with a control circuit are disclosed. A lower cavity (120) is formed in a device wafer (100) containing the control circuit (110), and the device wafer (100) is then processed so that the lower cavity (120) is exposed from a back side (100D) of the device wafer (100). A substrate (600) in which an upper cavity (610) is formed at a corresponding location is bonded to the back side (100D) of the device wafer (100) in such a manner that the piezoelectric vibrator (500) is sandwiched between the device wafer (100) and the substrate (600), with the upper cavity (610) and the lower cavity (120) being aligned with each other on opposing side of the piezoelectric vibrator (500), thus resulting in the formation of the crystal resonator and simultaneously achieving the integration of the crystal resonator with the control circuit (110). This crystal resonator is more compact in size, less power-consuming and able to integrate with other semiconductor components with an increased degree of integration.

### TECHNICAL FIELD

The present invention relates to the field of semiconductor technology and, in particular, to a structure and method for integrating a crystal resonator with a control circuit.

### BACKGROUND

A crystal resonator is a device operating on the basis of inverse piezoelectricity of a piezoelectric crystal. As key components of crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, existing crystal resonators are not only hard to be integrated with other semiconductor components and bulky themselves.

For example, common existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated integrated circuit by soldering or gluing additionally hinders the crystal resonators' miniaturization.

### SUMMARY OF THE INVENTION

It is an objective of the present invention to provide a method for integrating a crystal resonator with a control circuit, which overcomes the above described problems with conventional crystal resonators, i.e., a bulky size and difficult integration.

According to the present invention, the above objective is attained by a method for integrating a crystal resonator with a control circuit, including:

providing a device wafer having the control circuit formed therein;

forming, in the device wafer, a lower cavity with an opening at a back side of the device wafer;

providing a substrate and etching it so that an upper cavity of the crystal resonator is formed therein at a location corresponding to the lower cavity;

forming a piezoelectric vibrator including a top electrode, a piezoelectric crystal and a bottom electrode, which are formed either on the back side of the device wafer or on the substrate;

forming a connecting structure on the device wafer or on the substrate; and

bonding the substrate to the front side of the device wafer such that the piezoelectric vibrator is situated between the device wafer and the substrate, with the upper and lower cavities being located on opposing sides of the piezoelectric vibrator, and electrically connecting both the top and bottom electrodes of the piezoelectric vibrator to the control circuit through the connecting structure; and

electrically connecting both the top and bottom electrodes of the piezoelectric vibrator to the piezoelectric vibrator.

It is another objective of the present invention to provide a structure for integrating a crystal resonator with a control circuit, including:

a device wafer in which the control circuit and a lower cavity are formed, the lower cavity extending through the device wafer;

a substrate, which is bonded to the device wafer from the back side thereof, and in which an upper cavity is formed, the upper cavity having an opening aligned with the opening of the lower cavity;

a piezoelectric vibrator comprising a bottom electrode, a piezoelectric crystal and a top electrode, the piezoelectric vibrator arranged between the device wafer and the substrate so that the lower and upper cavities are on opposing sides of the piezoelectric vibrator; and

a connecting structure electrically connecting both the top and bottom electrodes of the piezoelectric vibrator to the control circuit.

In the proposed method, planar fabrication processes are utilized to form the lower cavity in the device wafer containing the control circuit and expose the lower cavity at the back side of the device wafer, followed by bonding the substrate to the back side of the device wafer. In this way, the crystal resonator and the control circuit are integrated on the same semiconductor wafer.

Therefore, in addition to allowing the crystal resonator to integrate with other semiconductor components with a higher degree of integration, the proposed method also enables a more compact size, enhanced miniaturization, reduced fabrication cost and lower power consumption of the resulting crystal resonator, compared with traditional crystal resonators (e.g., surface-mount ones).

### BRIEF DESCRIPTION OF THE DRAWINGS

FIG. 1 shows a flowchart schematically illustrating a method for integrating a crystal resonator with a control circuit according to a first embodiment of the present invention.

FIGS. 2a to 2j are schematic representations of structures resulting from steps in the method for integrating a crystal resonator with a control circuit according to the first embodiment of the present invention.

FIGS. 3a to 3d are schematic representations of structures resulting from steps in a method for integrating a crystal resonator with a control circuit according to a third embodiment of the present invention.

FIG. 4 is a schematic illustration of a structure for integrating a crystal resonator with a control circuit according to an embodiment of the present invention.

In these figures,

100—device wafer; AA—device area; 100U—front side; 100D—back side; 100A—substrate wafer; 100B—dielectric layer; 101—base layer; 102—buried oxide layer; 103—top silicon layer; 110—control circuit; 111—first circuit; 111T—first transistor; 111C—first interconnect; 112—second circuit; 112T—first transistor; 112C—first interconnect; 120—lower cavity; 211—first connecting wire; 212—second connecting wire; 221—first conductive plug; 222—second conductive plug; 300—planarized layer; 400—support wafer; 500—piezoelectric vibrator; 510—bottom electrode; 520—piezoelectric crystal; 530—top electrode; 600—substrate; 610—upper cavity; 700—third conductive plug; 710—first plastic encapsulation layer; 720—second plastic encapsulation layer.

### DETAILED DESCRIPTION

The core idea of the present invention is to provide a structure and method for integrating a crystal resonator with a control circuit, in which planar fabrication processes are utilized to integrate a piezoelectric vibrator on a wafer where the control circuit is formed. This, on the one hand, results in a size reduction of the crystal resonator and, on the other hand, allows integration of the crystal resonator with other semiconductor components with an increased degree of integration.

Specific embodiments of the proposed structure and method will be described below in greater detail with reference to the accompanying drawings. Features and advantages of the invention will be more apparent from the following description. Note that the accompanying drawings are provided in a very simplified form not necessarily drawn to exact scale and for the only purpose of helping to explain the disclosed embodiments in a more convenient and clearer way.

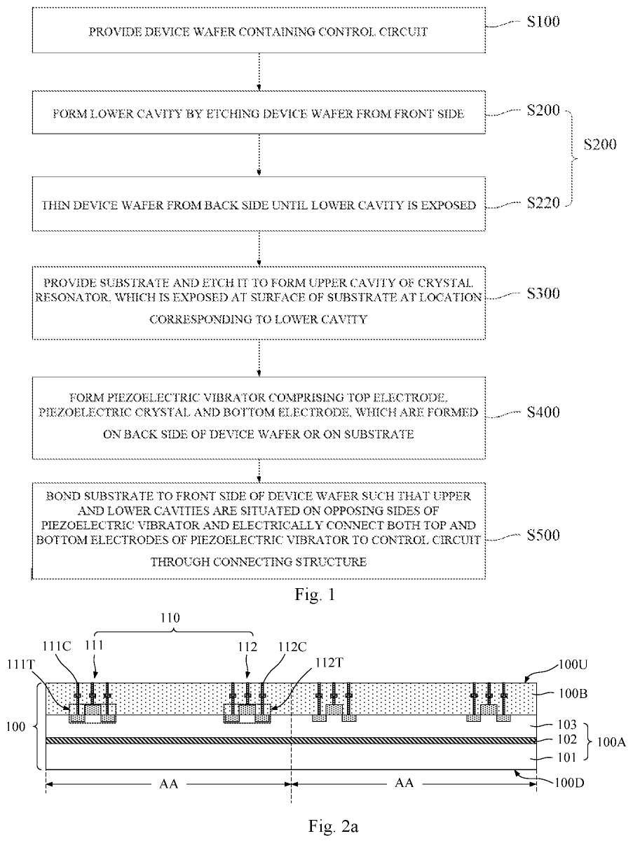

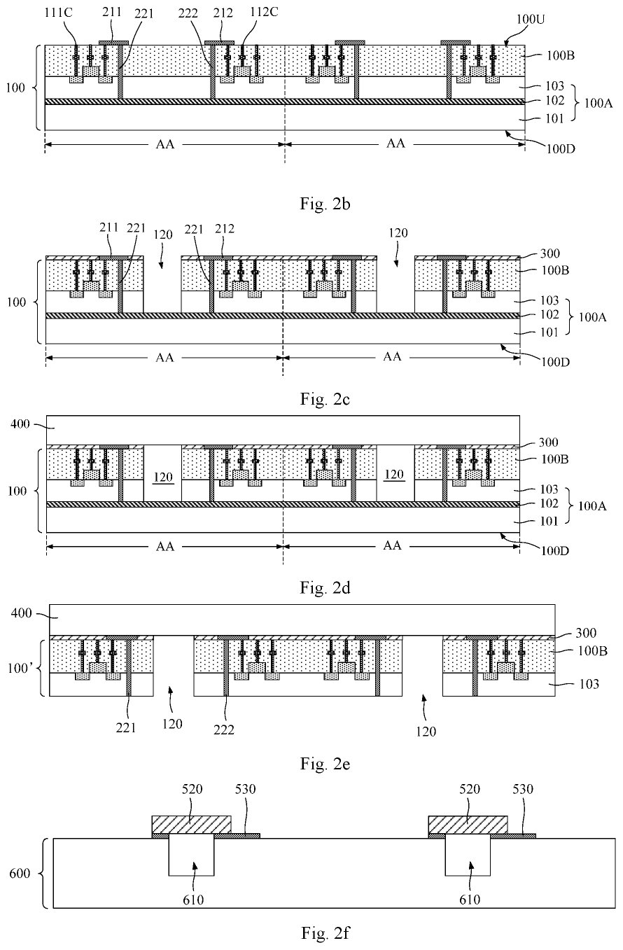

FIG. 1 shows a flowchart schematically illustrating a method for integrating a crystal resonator with a control circuit according to an embodiment of the present invention, and FIGS. 2a to 2j are schematic representations of structures resulting from steps in the method for integrating a crystal resonator with a control circuit according to an embodiment of the present invention. In the following, steps for forming the crystal resonator will be described in detail with reference to the figures.

In step S100, with reference to FIG. 2a, a device wafer 100 is provided, the device wafer 100 has a front side 100U and a back side 100D opposite to the front side, and a control circuit 110 is formed in the device wafer 100.

In this embodiment, at least some interconnects in the control circuit 110 extend to the front side 100U of the device wafer. It can be considered that these interconnects in the control circuit 110 are exposed at the front side 100U of the device wafer 100. This allows the control circuit 110 to be electrically connected to the subsequently formed piezoelectric vibrator so as to be able to apply an electrical signal thereto.

A plurality of crystal resonators may be formed on the same device wafer 100. Accordingly, there may be a plurality of device areas AA defined on the device wafer 100, and each crystal resonator may be formed in a respective one of the device areas AA.

The control circuit 110 may include a first circuit 111 and a second circuit 112, the first circuit 111 and the second circuit 112 may be electrically connected to a top electrode and a bottom electrode of the subsequently formed piezoelectric vibrator, respectively.

With continued reference to FIG. 2a, the first circuit 111 may include a first transistor 111T and a first interconnect 111C. The first transistor 111T may be buried within the device wafer 100, and the first interconnect 111C may be connected to the first transistor 111T and extend to the front side 100U of the device wafer 100. The first interconnect 111C may include conductive plugs electrically connected respectively to a gate, source and drain of the first transistor 111T.

Similarly, the second circuit 112 may include a second transistor 112T and a second interconnect 112C. The second transistor 112T may be buried within the device wafer 100, and the second interconnect 112C may be connected to the second transistor 112T and extend to the front side 100U of the device wafer 100. The second interconnect 112C may include conductive plugs electrically connected respectively to a gate, source and drain of the second transistor 112T.

A method for forming the control circuit 110 may include:

providing a substrate wafer 100A and forming the first and second transistors 111T, 112T on the substrate wafer 100A; and

then forming a dielectric layer 100B over the substrate wafer 100A, the dielectric layer 100B covers the first and second transistors 111T, 112T, and forming the first and second interconnects 111C, 112C in the dielectric layer 100B, resulting in the formation of the device wafer 100.

In other words, the device wafer 100 includes the substrate wafer 100A and the dielectric layer 100B formed on the substrate wafer 100A, and a surface of the dielectric layer 100B facing away from the substrate wafer 100A provides the front side 100U. The first and second transistors 111T, 112T are both formed on the substrate wafer 100A and are covered by the dielectric layer 100B, and the first and second interconnect 111C, 112C are both so formed in the dielectric layer 100B as to extend to the surface of the dielectric layer 100B facing away from the substrate wafer.

The substrate wafer 100A may be either a silicon wafer or a silicon-on-insulator (SOI) wafer. In this embodiment, the substrate wafer 100A is a SOI wafer including a base layer 101, a buried oxide layer 102 and a top silicon layer 103, which are sequentially stacked in this order in the direction from the back side 100D to the front side 100U.

It is to be noted that, in this embodiment, the interconnects in the control circuit 110 extend to the front side 100U of the device wafer, while the piezoelectric vibrator is to be subsequently formed on the back side 100D of the device wafer. Accordingly, a connecting structure may be subsequently formed to lead connection ports of the control circuit 110 for electrically connecting the piezoelectric vibrator from the front to back side of the device wafer and brought into electrical connection with the subsequently formed piezoelectric vibrator there.

Specifically, the connecting structure may include a first connection for electrically connecting the first interconnect 111C to the bottom electrode of the subsequently formed piezoelectric vibrator and a second connection for electrically connecting the second interconnect 112C to the top electrode of the subsequently formed piezoelectric vibrator.

In addition, the first connection may include a first conductive plug 221 configured for electrical connection at its opposing ends respectively to the first interconnect 111a and the subsequently formed bottom electrode. That is, the first conductive plug 221 may serve to lead a connecting port of the first interconnect 111a in the control circuit from a front side of the control circuit to a back side thereof so as to enable electrical connection of the bottom electrode subsequently formed on the back side of the device wafer to the control circuit from the back side of the control circuit.

Optionally, in this embodiment, the first connection may further include a first connecting wire 211 formed, for example, on the front side of the device wafer. The first connecting wire 211 may connect one end of the first conductive plug 221 to the first interconnect, and the other end of the first conductive plug 221 may be electrically connected to the bottom electrode.

In alternative embodiments, the first connecting wire in the first connection may be formed on the back side of the device wafer. In this case, the first connecting wire may connect one end of the first conductive plug 221 to the bottom electrode, and the other end of the first conductive plug 221 may be electrically connected to the first interconnect in the control circuit.

Similarly, the second connection may include a second conductive plug 222 configured for electrical connection at its opposing ends respectively to the second interconnect 112a and the subsequently formed top electrode. That is, the second conductive plug 222 may serve to lead a connecting port of the second interconnect 112a in the control circuit from the front to back side of the control circuit so as to enable electrical connection of the top electrode subsequently formed on the back side of the device wafer to the control circuit from the back side of the control circuit.

Additionally, in this embodiment, the second connection may further include a second connecting wire 212 formed, for example, on the front side of the device wafer. The second connecting wire 212 may connect one end of the second conductive plug 222 to the second interconnect, and the other end of the second conductive plug 222 may be electrically connected to the top electrode.

In alternative embodiments, the second connecting wire in the second connection may be formed on the back side of the device wafer. In this case, the second connecting wire may connect one end of the second conductive plug 222 to the top electrode, and the other end of the second conductive plug 222 may be electrically connected to the second interconnect in the control circuit.

The first conductive plug 221 in the first connection and the second conductive plug 222 in the second connection may be formed in a single process step. The first connecting wire 211 in the first connection and the second connecting wire 212 in the second connection may also be formed in a single process step.

Specifically, in this embodiment, the formation of the first connection that includes the first conductive plug 221 and the first connecting wire 211 on the front side of the device wafer and of the second connection that includes the second conductive plug 222 and the second connecting wire 212 on the front side of the device wafer may include the steps as follows:

Step 1: Etch the device wafer 100 from the front side 100U thereof to form a first connecting hole and a second connecting hole therein.

Step 2: Fill a conductive material in the first and second connecting holes, resulting in the formation of the first and second conductive plugs 221, 222 that are to be connected to the first and second circuits 111, 112, respectively, as shown in FIG. 2b.

In this embodiment, both the first and second conductive plugs 221, 222 are located at the bottom closer to the back side 100D of the device wafer than the control circuit. Specifically, the first and second transistors 111T, 112T may be both formed within the top silicon layer 103 above the buried oxide layer 102, while the first and second conductive plugs 221, 222 may each penetrate sequentially through the dielectric layer 100B and the top silicon layer 103 and terminate at the buried oxide layer 102. Thus, it may be considered that the buried oxide layer 102 can serve as an etch stop layer for the etching process for forming the first and second connecting holes. In this way, high etching accuracy can be achieved for the etching process.

Step 3: Form the first connecting wire 211 and the second connecting wire 212 on the front side of the device wafer 100, the first connecting wire 211 connects the first conductive plug 221 to the first interconnect 111C and the second connecting wire 212 connects the second conductive plug 222 to the second interconnect 112C, as also shown in FIG. 2b.

In a subsequent process, the device wafer may be thinned from the back side so that the first and second conductive plugs are exposed from the processed back side and brought into electrical connection with the top and bottom electrodes of the piezoelectric vibrator on the back side.

In embodiments with the first connecting wire in the first connection and the second connecting wire in the second connection being both formed on the back side of the device wafer, the formation of the first connection that includes the first conductive plug and the first connecting wire and of the second connection that includes the second conductive plug and the second connecting wire may include, for example:

first, forming a first connecting hole and a second connecting hole by etching the device wafer from the front side thereof;

then forming the first conductive plug that is electrically connected to the first interconnect and the second conductive plug that is electrically connected to the second interconnect by filling a conductive material into the first and second connecting holes;

subsequently, thinning the device wafer from the back side thereof so that the first and second conductive plugs are exposed; and

forming, on the back side of the device wafer, the first connecting wire that is connected to the first conductive plug at one end and configured for electrical connection with the bottom electrode at the other end and the second connecting wire that is connected to the second conductive plug at one end and configured for electrical connection with the top electrode at the other end.

It is to be noted that although the first and second conductive plugs 221, 222 have been described above as being formed from the front side of the device wafer prior to the formation of the first and second connecting wires, the first and second conductive plugs 221, 222 may be alternatively formed from the back side of the device wafer subsequent to the thinning of the device wafer, as will be described in greater detail below.

In addition, in a subsequent process, a support wafer may be bonded to the front side 100U of the device wafer 100. According, subsequent to the formation of the first and second connecting wires 211, 212, the method may optionally further include forming, on the front side 100U of the device wafer 100, a planarized layer 300 which provides the device wafer 100 with a flatter bonding surface.

Specifically, referring to FIG. 2c, the planarized layer 300 may be formed on the front side 100U of the device wafer 100 and may have a top surface not lower than those of the first and second connecting wires 211, 212. For example, the planarized layer 300 may cover the device wafer 100 and the first and second connecting wires 211, 212 so as to provide a flat top surface. Alternatively, the top surface of the planarized layer 300 may also be flush with those of the first and second connecting wires 211, 212, and this can also achieve the purpose of providing the device wafer 100 with a flat bonding surface.

In this embodiment, the planarized layer 300 may be formed using a polishing process. In this case, for example, the first and second connecting wires 211, 212 may serve as a polish stop such that the top surface of the formed planarized layer 300 is flush with those of the first and second connecting wires 211, 212, and all these surfaces may make up a bonding surface for the device wafer 100.

In step S200, with reference to FIGS. 2c to 2e, a lower cavity 120 with an opening at the back side of the device wafer is formed in the device wafer 100.

In this embodiment, the lower cavity 120 may be formed, for example, using a method including steps S210 and S220 below.

In step S210, with reference to FIG. 2c, the lower cavity 120 of the crystal resonator is formed by etching the device wafer 100 from the front side of the device wafer 100.

Specifically, the lower cavity 120 extends deep into the device wafer 100 from the front side 100U and may have a bottom that is closer to the back side 100D of the device wafer than the bottom of the control circuit 110.

In this embodiment, the lower cavity 120 may be formed subsequent to the formation of the planarized layer 300 by sequentially etching through the planarized layer 300 and the device wafer 100. Specifically, an etching process for forming the lower cavity 120 may proceed sequentially through the planarized layer 300, the dielectric layer 100B and the top silicon layer 103 and stop at the buried oxide layer 102.

Thus, in this embodiment, the buried oxide layer 102 may serve as an etch stop layer for both the etching process for forming the first and second connecting holes for the first and second conductive plugs 221, 222 and the etching process for forming the lower cavity 120. As a result, bottoms of the resulting first and second conductive plugs 221, 222 are at the same or similar level as that of the lower cavity 120. As such, it can be ensured that the first conductive plug 221, second conductive plug 222 and lower cavity 120 can be all exposed when the device wafer is subsequently thinned from the back side 100D.

It is to be noted that the relative positions of the lower cavity 120 and the first and second circuits shown in the figures are merely for illustration, and in practice, the arrangement of the first and second circuits may depend on the actual circuit layout requirements, without limiting the present invention.

In step S220, with reference to FIGS. 2d to 2e, the device wafer 100 is thinned from the back side 100D until the lower cavity 120 is exposed.

In this embodiment, the lower cavity 120 is bottomed at the buried oxide layer 102. Therefore, as a result of the thinning of the device wafer, the base layer 101 and the buried oxide layer 102 are sequentially stripped away, and the top silicon layer 103 and lower cavity 120 are both exposed. The exposed lower cavity 120 provides a space in which the subsequently formed piezoelectric vibrator can vibrate. Moreover, the first and second conductive plugs 221, 222 are also exposed as a result of thinning the device wafer. The exposure of the first and second conductive plugs 221, 222 makes it possible to electrically connect them to the subsequently formed piezoelectric vibrator.

Optionally, with reference to FIG. 2d, before the device wafer 100 is thinned, a support wafer 400 may be bonded to the front side of the device wafer 100, which can provide a support for the thinning process. Additionally, the support wafer 400 can close the opening of the lower cavity exposed at the front side of the device wafer. Therefore, it can be considered that, in this embodiment, the support wafer 400 also serves as a cap substrate for closing the opening of the lower cavity at the front side of the device wafer.

It is to be noted that, in this embodiment, the lower cavity 120 is formed by etching the device wafer 100 from the front side and thinning the device wafer 100 from the back side so that the opening of the lower cavity 120 is exposed at the back side of the device wafer 100.

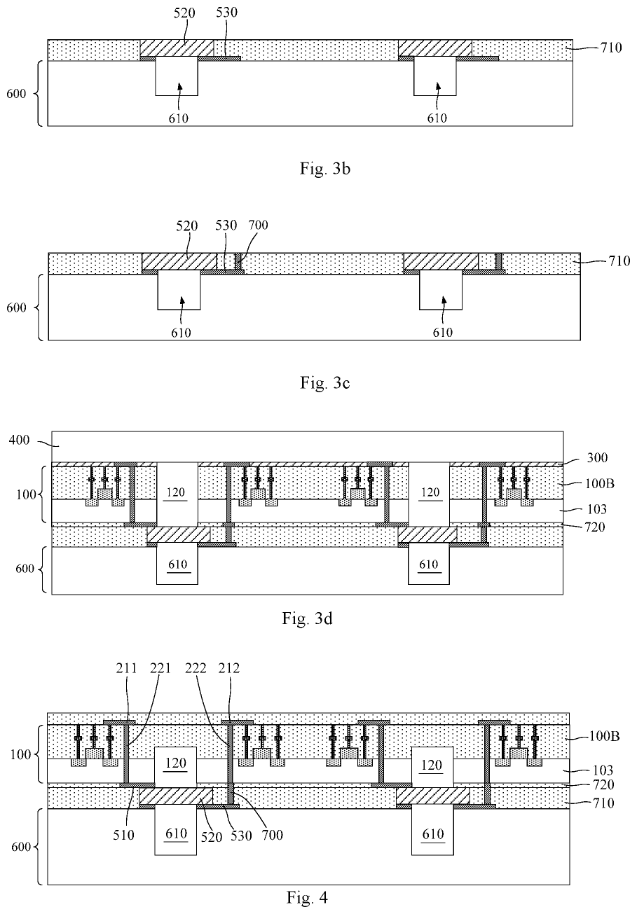

However, referring to FIG. 4, in other embodiments, the lower cavity 120 of the crystal resonator may be alternatively formed by etching the device wafer from the back side. In still other embodiments, the etching process on the back side of the device wafer may be preceded by a thinning of the device wafer.

With particular reference to FIG. 4, in one specific embodiment, the formation of the lower cavity by etching the device wafer from the back side thereof may include, for example, the following steps.

At first, the device wafer is thinned from the back side. In case of the substrate wafer being a SOI wafer, this may involve sequential removal of the base layer and the buried oxide layer of the substrate wafer. Of course, the thinning of the substrate wafer may alternatively involve partial removal of the base layer, complete removal of the base layer and hence exposure of the buried oxide layer, or the like.

Next, the device wafer is etched from the back side so that the lower cavity is formed. It is to be noted that the lower cavity resulting from the etching of the device wafer may have a depth as practically required, and the present invention is not limited to any particular depth of the lower cavity. For example, after the device wafer is thinned and the top silicon layer 103 is exposed, the top silicon layer 103 may be etched to form the lower cavity therein. Alternatively, the etching process may proceed through the top silicon layer 103 and further into the dielectric layer 100B, so that the resulting lower cavity 120 extends from the top silicon layer 103 down into the dielectric layer 100B.

It is to be also noted that during the formation of the lower cavity as shown in FIG. 4, prior to the formation of the lower cavity, another support wafer may be optionally bonded to the front side of the device wafer to enhance support for the device wafer. Of course, instead of bonding the support wafer, it is also plausible to form a plastic encapsulation layer on the front side of the device wafer, which covers all the components exposed on the front side of the device wafer.

As discussed above, in other embodiments, the thinning of the device wafer may be followed by forming the first conductive plug 221 of the first connection and the second conductive plug 222 of the first connection from the back side of the device wafer 100.

Specifically, a method for forming the first and second connecting wires on the front side of the device wafer 100, forming the first and second conductive plugs 221, 222 from the back side of the device wafer 100, connecting the first conductive plug 221 to the first connecting wire 211 and connecting the second conductive plug 222 to the second connecting wire 212 may include the steps below.

At first, prior to the bonding of the support wafer 400, the first and second connecting wires that are electrically connected to first and second interconnects, respectively, are formed on the front side of the device wafer 100.

Next, after the device wafer 100 is thinned, it is etched from the back side to form therein first and second connecting holes, both of which extend through the device wafer 100 so that the first and second connecting wires 211, 212 are exposed respectively in the holes.

Subsequently, a conductive material is filled in the first and second connecting holes, resulting in the formation of the first and second conductive plugs 221, 222. The first conductive plug 221 is connected at one end to the first connecting wire 211 and configured for electrical connection with the bottom electrode of the piezoelectric vibrator at the other end. The second conductive plug 222 is connected at one end to the second connecting wire 212 configured for electrical connection with the top electrode of the piezoelectric vibrator at the other end.

In an alternative embodiment, a method for forming the first and second connecting wires on the back side of the device wafer 100, forming the first and second conductive plugs from the back side of the device wafer 100, connecting the first conductive plug 221 to the first connecting wire and connecting the second conductive plug 222 to the second connecting wire may include the steps detailed below.

At first, the device wafer 100 is thinned from the back side, followed by etching the device wafer 100 from the back side and thus forming first and second connecting holes therein.

Next, a conductive material is filled in the first and second connecting holes, resulting in the formation of the first and second conductive plugs. The first conductive plug is electrically connected at one end to the first interconnect, and the second conductive plug is electrically connected at one end to the second interconnect.

Subsequently, the first and second connecting wires are formed on the back side of the device wafer 100. One end of the first connecting wire is connected to the other end of the first conductive plug, and the other end of the first connecting wire is configured for electrical connection with the bottom electrode. One end of the second connecting wire is connected to the other end of the second conductive plug, and the other end of the second connecting wire is configured for electrical connection with the top electrode.

In step S300, with reference to FIG. 2f, a substrate 600 is provided and etched so that an upper cavity 610 of the crystal resonator is formed therein, which is exposed from a surface of the substrate 600 and aligned with the lower cavity 120. In a subsequent process for forming the piezoelectric vibrator, the upper and lower cavities 610, 120 may be positioned in alignment with each other at opposing side of the piezoelectric vibrator.

On the substrate 600, there may be also defined a plurality of device areas AA corresponding to those on the device wafer 100, and the lower cavity 120 may be formed in one of the device areas AA on the device wafer 100.

In step S400, a piezoelectric vibrator including a top electrode, a piezoelectric crystal and a bottom electrode is formed. Each of the top electrode, the piezoelectric crystal and the bottom electrode may be formed either on the back side of the device wafer or on the substrate.

In other words, it is possible that the top electrode, the piezoelectric crystal and the bottom electrode in the piezoelectric vibrator are all formed on the back side of the device wafer 100, or on the substrate 600. It is also possible that the bottom electrode of the piezoelectric vibrator is formed on the back side of the device wafer 100, with the top electrode and piezoelectric crystal of the piezoelectric vibrator being formed as a stack on the substrate. It is still possible that the bottom electrode and the piezoelectric crystal of the piezoelectric vibrator are formed as a stack on the back side of the device wafer 100, with the top electrode of the piezoelectric vibrator being formed on the substrate.

Referring to FIGS. 2f and 2g, in this embodiment, the top electrode 530, piezoelectric crystal 520 and the bottom electrode 510 in the piezoelectric vibrator 500 are all formed on the substrate 600. The piezoelectric vibrator 500 is positioned above the upper cavity 610, with its peripheral edge portions resting on top edges of the upper cavity 610.

The first circuit 111 is electrically connected to the bottom electrode 510, and the second circuit 112 to the top electrode 530. As such, an electrical signal can be applied to the bottom and top electrodes 510, 530 to form an electric field between the bottom electrode 510 and the top electrode 530, which causes the piezoelectric crystal 520 to change its shape. The magnitude of the shape change of the piezoelectric crystal 520 depends on the strength of the electric field, and when the electric field between the top and bottom electrodes 530, 510 is inverted, the piezoelectric crystal 520 will responsively change its shape in the opposite direction. Therefore, when the control circuit 110 applies an AC signal to the top and bottom electrodes 530, 510, the piezoelectric crystal 520 will change shape alternately in opposite directions and thus alternately contract and expand due to oscillations of the electric field. As a result, the piezoelectric crystal 520 will vibrate mechanically.

Specifically, the formation of the piezoelectric vibrator 500 on the substrate 600 may include, for example, the steps as follows:

Step 1: Form the top electrode 530 at a predetermined location on a surface of the substrate 600, as shown in FIG. 2f. In this embodiment, the top electrode 530 surrounds the upper cavity 610. In a subsequent process, the top electrode 530 may be brought into electrical connection with the second conductive plug 222 and hence with the second interconnect in the second circuit 112.

The top electrode 530 may be formed of, for example, silver, and the formation may involve successive processes of thin-film deposition, photolithography and etching. Alternatively, the top electrode 530 may be formed using a vapor deposition process.

Step 2: With continued reference to FIG. 2f, bond the piezoelectric crystal 520 to the top electrode 530, so that the piezoelectric crystal 520 is located above the upper cavity 610, with its peripheral edge portions residing on the top electrode 530. The piezoelectric crystal 520 may be, for example, a quartz crystal plate.

In this embodiment, the upper cavity 610 may be narrower than the piezoelectric crystal 520 so that the piezoelectric crystal 520 can be arranged with its peripheral edge portions residing on the surface of the substrate, thus covering an opening of the upper cavity 610.

However, in other embodiments, the upper cavity may be made up of, for example, a first portion and a second portion. The first portion may be deeper in the substrate than the second portion, and the second portion may be adjacent to the surface of the substrate. Additionally, the first portion may be narrower than the piezoelectric crystal 520, and the second portion may be broader than the piezoelectric crystal. In this way, the piezoelectric crystal 520 may be at least partially received in the second portion, with its peripheral edge portions residing on top edges of the first portion. In addition, it is devisable that the opening of the upper cavity is wider than the piezoelectric crystal.

Further, the top electrode 530 may have an extension laterally extending beyond the piezoelectric crystal 520 thereunder. In a subsequent process, the top electrode 530 may be connected to the second conductive plug 222 via the extension.

Step 3: Form the bottom electrode 510 on the piezoelectric crystal 520, as shown in FIG. 2g. In a subsequent process, the bottom electrode 510 may be brought into electrical connection with the first conductive plug 221 and hence with the first interconnect in the first circuit 111. As with the top electrode 530, the bottom electrode 510 may also be formed of, for example, silver, using a vapor deposition process.

It is to be noted that, in this embodiment, the bottom electrode 510 is to be brought into contact with the first conductive plug 221 in the device wafer 100 as a result of the subsequent bonding process. In order to ensure a size of the bottom electrode 510 that is sufficiently large to enable full contact of the bottom electrode 510 with the first conductive plug 221, in this embodiment, the bottom electrode 510 has an extension laterally extending beyond the piezoelectric crystal 520, and the contact of the bottom electrode with the first conductive plug 221 is to be made at this extension.

Specifically, a method for forming the bottom electrode 510 may include the steps below.

In a first step, with reference to FIG. 2g, a first plastic encapsulation layer 710 is formed on the substrate 600, the first plastic encapsulation layer 710 covers the substrate 600, and from which the piezoelectric crystal 520 is exposed. It is to be noted that, in this embodiment, since the top electrode 530 is formed under the piezoelectric crystal 520, with the extension thereof extending laterally beyond the piezoelectric crystal 520, the first plastic encapsulation layer 710 also covers the extension of the top electrode 530.

In addition, a top surface of the first plastic encapsulation layer 710 may not be higher than that of the piezoelectric crystal 520. In this embodiment, the formation of the first plastic encapsulation layer 710 may involve planarizing the first plastic encapsulation layer 710 so that its top surface is flush with that of the piezoelectric crystal 520.

In a second step, with continued reference to FIG. 2g, the bottom electrode 510 is formed on the surface of the piezoelectric crystal 520. The bottom electrode 510 has an extension extending laterally beyond the piezoelectric crystal 520 over the first plastic encapsulation layer 710. In a subsequent process, the bottom electrode 510 may be connected to the first conductive plug 221 via the extension.

It is to be noted that, in this embodiment, the top electrode 530, the piezoelectric crystal 520 and the bottom electrode 510 are successively formed over the substrate 600 using semiconductor processes. However, in other embodiments, it is also possible to form the top and bottom electrodes on opposing sides of the piezoelectric crystal and then bond the three as a whole onto the substrate.

Optionally, subsequent to the formation of the bottom electrode 510, the method may further include forming a second plastic encapsulation layer on the first plastic encapsulation layer 710, which provides the substrate 600 with a fatter surface that is favorable to the subsequent bonding process.

With reference to FIG. 2h, the second plastic encapsulation layer 720 formed on the first plastic encapsulation layer 710 may have a top surface not higher than that of the bottom electrode 510 so that the bottom electrode 510 remains exposed. In this embodiment, the formation of the second plastic encapsulation layer 720 may involve planarizing the second plastic encapsulation layer 720 so that its top surface is flush with that of the bottom electrode 510. Moreover, the central portion of the piezoelectric crystal 520 may also be exposed from the second plastic encapsulation layer 720. In this way, when the substrate 600 is subsequently bonded to the device wafer 100, the central portion of the piezoelectric crystal 520 is aligned with the lower cavity 120 in the device wafer 100.

As discussed above, the bottom electrode 510 on the substrate 600 is brought into electrical connection with the control circuit by the first connection as a result of the subsequent bonding process. In this embodiment, the first connection includes the first conductive plug 221 and the first connecting wire 211, and the bottom electrode 510 is exposed at the top surface of the second plastic encapsulation layer 720 and includes the aforementioned extension. The first conductive plug 221 is exposed at the top from the back side of the device wafer 100. As a result of the bonding of the device wafer 100 and the substrate 600, the bottom electrode 510 may reside on the back side of the device wafer 100, with its extension coming into direct contact with the first conductive plug 221. In this way, the bottom electrode 510 is electrically connected to the control circuit via the first connection.

As another result of the subsequent bonding process, the top electrode 530 on the substrate 600 is brought into electrical connection with the second conductive plug 222 on the device wafer 100 by the second connection. As described above, in this embodiment, the second connection includes the second conductive plug 222 and the second connecting wire 212.

The second connection may further include a third conductive plug that connects the extension of the top electrode 530 that is buried within the first plastic encapsulation layer 710 to the second conductive plug 222. Specifically, in this embodiment, subsequent to the successive formation of the top electrode 530 and the piezoelectric crystal 520 on the substrate 600, the third conductive plug may be so formed on the substrate 600 as to be electrically connected to the top electrode 530.

Accordingly, in this embodiment, the formation of the second connection may further include the steps below.

At first, a plastic encapsulation layer is formed on the surface of the substrate 600. In this embodiment, this plastic encapsulation layer is made up of the aforementioned first and second plastic encapsulation layers 710, 720.

Next, a through hole is formed in the plastic encapsulation layer, in which the top electrode 530 is exposed. In this embodiment, the through hole may be formed by sequentially etching through the second plastic encapsulation layer 720 and the first plastic encapsulation layer 710.

Subsequently, a conductive material is filled in the through hole, resulting in the formation of the third conductive plug 700, which is electrically connected at one end to the top electrode 530.

In this embodiment, the third conductive plug 700 is connected to the extension of the top electrode 530 at one end and exposed at the top surface of the second plastic encapsulation layer 720 at the other end. In this way, the other end of the third conductive plug 700 can be brought into electrical connection with the second conductive plug 222 when the substrate 600 is bonded to the device wafer 100.

In step S500, with reference to FIG. 2j, the substrate 600 is bonded to the back side of the device wafer 100 such that the piezoelectric vibrator 500 is sandwiched between the device wafer 100 and the substrate 600, with the upper and lower cavities 610, 120 being located on opposing sides of the piezoelectric vibrator 500. In addition, the top and bottom electrodes 530, 510 of the piezoelectric vibrator 500 are both electrically connected to the control circuit through the connecting structure.

As discussed above, the device wafer 100 and the substrate 600 may be so bonded that, in the control circuit, the first circuit 111 is electrically connected to the bottom electrode 510 by the first connection (including the first connecting wire 211 and the first conductive plug 221) and the second circuit 112 is electrically connected to the top electrode 530 by the second connection (including the second connecting wire 212, the second conductive plug 222 and the third conductive plug 700). In this way, the control circuit can apply an electrical signal to the electrodes sandwiching the piezoelectric crystal 520, which causes the piezoelectric crystal 520 to change its shape and vibrate in the upper and lower cavities 610, 120.

The bonding of the device wafer 100 and the substrate 600 may be accomplished by a method including, for example, applying adhesive layer(s) to the device wafer 100 and/or the substrate 600 and bonding the device wafer 100 and the substrate 600 together by means of the adhesive layer(s). Specifically, an adhesive layer may be applied to the substrate with the piezoelectric crystal formed thereon in such a manner that the surface of the piezoelectric crystal is exposed at a surface of the adhesive layer, and the substrate without the piezoelectric crystal formed thereon may be then bonded to the adhesive layer.

In this embodiment, the piezoelectric vibrator 500 is formed on the substrate 600. Accordingly, the bonding of the device wafer 100 and the substrate 600 may be accomplished by a method including, for example, applying an adhesive layer to the substrate 600 so that the surface of the piezoelectric vibrator 500 is exposed at a surface of the adhesive layer, and then bonding together the substrate 600 and the device wafer 100 by means of the adhesive layer.

Therefore, in this embodiment, the top electrode 530, the piezoelectric crystal 520 and the bottom electrode 510 of the piezoelectric vibrator 500 are all formed on the substrate 600, and the piezoelectric vibrator 500 covers an opening of the upper cavity 610. In addition, the bonding is so performed that the lower cavity 120 is located on the side of the piezoelectric vibrator 500 away from the upper cavity 610 and the crystal resonator is thus formed. In addition, the crystal resonator is electrically connected to the control circuit in the device wafer 100, achieving the integration of the crystal resonator with the control circuit.

Further, with the support wafer 400 supporting the device wafer from the front side, and with the connecting structure leading connecting ports of the control circuit from the front to the back side, the piezoelectric vibrator 500 is enabled to be electrically connected to the control circuit 110 from the back side of the control circuit 110. This allows significantly increased flexibility in the fabrication of the piezoelectric vibrator 500.

Furthermore, subsequent to the bonding of the substrate 600, the support wafer may be retained as a cap substrate for closing the opening of the lower cavity exposed at the front side of the device wafer. Alternatively, the support wafer may be removed and a separate cap substrate may be bonded to the front side of the device wafer to close the opening of the lower cavity exposed at the front side of the device wafer.

### Embodiment 2

Differing from the first embodiment, the top electrode 530, the piezoelectric crystal 520 and the bottom electrode 510 of the piezoelectric vibrator 500 are all formed on the back side of the device wafer 100 and the piezoelectric vibrator 500 covers and closes an opening of the lower cavity 120 in accordance with a second embodiment. In addition, after the crystal resonator is electrically connected to the control circuit in the device wafer 100, a bonding process is performed so that the upper cavity 610 is located on the side of the piezoelectric vibrator 500 away from the lower cavity 120. Forming the crystal resonator in this way also achieves integration of the crystal resonator with the control circuit.

Reference can be made to the description of the first embodiment for details in the provision of the device wafer containing the control circuit and the formation of the lower cavity in the device wafer, and these are not described here again for the sake of brevity.

In this embodiment, the formation of the piezoelectric vibrator on the back side of the device wafer 100 may include the steps below.

At first, the bottom electrode 510 is formed at a predetermined location on the back side of the device wafer 100. In this embodiment, the bottom electrode 510 is positioned around the lower cavity 120.

Then, the piezoelectric crystal 520 is bonded to the bottom electrode 510. In this embodiment, the piezoelectric crystal 520 is so bonded above the lower cavity 120 that it covers and closes an opening of the lower cavity 120, with the peripheral edge portions of the piezoelectric crystal 520 residing on the bottom electrode 510.

Next, the top electrode 530 is formed on the piezoelectric crystal 520.

Of course, in other embodiments, it is also possible to form the top and bottom electrodes respectively on the opposing sides of the piezoelectric crystal and then bond the three as a whole to the back side of the device wafer 100.

In this embodiment, the bottom electrode 510 has an extension extending beyond the piezoelectric crystal 520 and coming into electrical connection with the first conductive plug in the first connection. Additionally, the second connection further includes the third conductive plug that electrically connects the top electrode 530 to the second conductive plug.

Specifically, the formation of the third conductive plug in the second connection may precede the formation of the top electrode and include, for example, the steps as follows:

Step 1: Form a plastic encapsulation layer on the back side of the device wafer 100. In this embodiment, the plastic encapsulation layer covers the surface of the device wafer 100, with the piezoelectric crystal 520 being exposed therefrom.

Step 2: Form a through hole in the plastic encapsulation layer and fill a conductive material in the through hole, thereby resulting in the formation of the third conductive plug. The resulting third conductive plug is electrically connected to the second conductive plug at the bottom and exposed from the plastic encapsulation layer at the top.

Step 3: Form the top electrode 530 in such a manner that the top electrode 530 extends beyond the piezoelectric crystal 520 over the top of the third conductive plug and thus comes into electrical connection with the third conductive plug. Alternatively, subsequent to the formation of the top electrode 530, an interconnecting wire may be formed thereon, which extends beyond the top electrode over the third conductive plug. In this way, the top electrode is electrically connected to the third conductive plug via the interconnecting wire.

In addition, the bonding of the device wafer 100 and the substrate 600 may include: applying an adhesive layer to the back side of the device wafer 100 in such a manner that the surface of the piezoelectric crystal 520 is exposed from the adhesive layer; and then bonding the device wafer 100 and the substrate 600 together by means of the adhesive layer.

The bonding may be so carried out that the upper cavity in the substrate 600 is located on the side of the piezoelectric crystal 520 away from the lower cavity. The upper cavity may be broader than the piezoelectric crystal so that the piezoelectric crystal can be accommodated within the upper cavity.

### Embodiment 3

Differing from the first and second embodiments in which the top electrode, the piezoelectric crystal and the bottom electrode of the piezoelectric vibrator are all formed either on the substrate or on the device wafer, in accordance with a third embodiment, the top electrode and piezoelectric crystal are formed on the substrate, while the bottom electrode is formed on the back side of the device wafer.

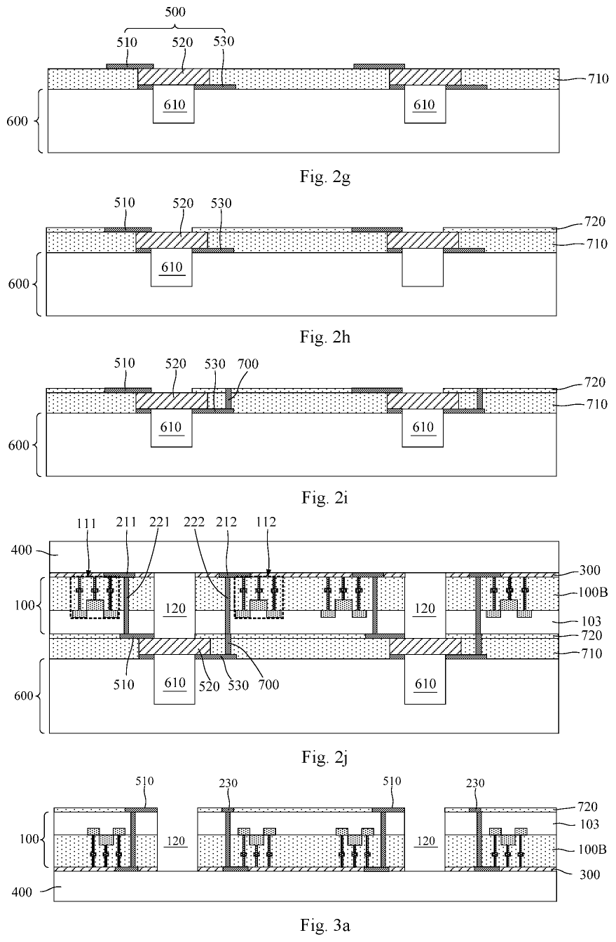

FIGS. 3a to 3d are schematic representations of structures resulting from steps in the method for integrating a crystal resonator with a control circuit according to the third embodiment of the present invention. In the following, steps for forming the crystal resonator will be described in detail with reference to the figures.

Referring now to FIG. 3a, the device wafer 100 is provided, the device wafer 100 having the control circuit formed therein, and the bottom electrode 510 is formed on the back side of the device wafer 100 so that the bottom electrode 510 is electrically connected to the first conductive plug in the connecting structure.

During the formation of the bottom electrode 510, a rewiring layer 230 may be formed on the device wafer 100, which covers the second conductive plug in the connecting structure.

Subsequent to the formation of the bottom electrode 510, the method may further include forming a second plastic encapsulation layer 720 on the device wafer 100, which has a surface that is not higher than that of the bottom electrode 510 so that the bottom electrode 510 remains exposed. In this embodiment, the surface of the second plastic encapsulation layer 720 is also not higher than that of the rewiring layer 230 so that the rewiring layer 230 is also exposed. In this way, the subsequent bonding process may be so performed that the bottom electrode 510 is positioned on one side of the piezoelectric crystal, with the rewiring layer 230 being electrically connected to the top electrode located on the other side of the piezoelectric crystal.

The formation of the second plastic encapsulation layer 720 may involve a planarization process for making the surface of the second plastic encapsulation layer 720 flush with that of the bottom electrode 510. In this way, a significant improved surface flatness can be provided to the device wafer 100, which is favorable to the subsequent bonding process.

With continued reference to FIG. 3a, in this embodiment, subsequent to the successive formation of the bottom electrode 510 and the second plastic encapsulation layer 720, the lower cavity 120 can be formed by successively etching through the second plastic encapsulation layer 720 and the dielectric layer 100B so that the bottom electrode 510 is positioned around the lower cavity 120.

Referring to FIG. 3b, the substrate 600 is provided and the top electrode 530 and piezoelectric crystal 520 are successively formed thereon above the upper cavity. The top electrode may be formed using a vapor deposition process or a thin-film deposition process, followed by bonding the piezoelectric crystal to the top electrode.

Specifically, the top electrode 530 is positioned around the upper cavity 610 and will be electrically connected to the rewiring layer 230 on the device wafer 100 and hence to the second interconnect 112a in the second circuit 112 in a subsequent process. Moreover, the piezoelectric crystal 520 may be so positioned that a central portion thereof is aligned with the upper cavity 310 in the substrate 300, with its peripheral edge portions residing on top edges of the top electrode 530. Further, an extension of the top electrode 530 may extend beyond the piezoelectric crystal 520 thereunder.

With continued reference to FIG. 3b, in this embodiment, subsequent to the formation of the piezoelectric crystal 520, the method may further include forming a first plastic encapsulation layer 710 on the substrate 600, the first plastic encapsulation layer 710 covers the substrate 600 and the extension of the top electrode 530. The first plastic encapsulation layer 710 may have a surface not higher than that of the piezoelectric crystal 520 so that the piezoelectric crystal 520 is exposed therefrom.

Similarly, in this embodiment, the formation of the first plastic encapsulation layer 710 may also involve a planarization process for making the surface of the first plastic encapsulation layer 710 flush with that of the piezoelectric crystal 520. In this way, the substrate 300 may be provided with a flatter surface, which is favorable to the subsequent bonding process.

Subsequently, referring to FIG. 3c, the third conductive plug 700 of the connecting structure is formed on the device wafer or in the substrate in order to electrically connect the top electrode 530 to the second conductive plug. In this embodiment, the top electrode 530 and the piezoelectric crystal 520 are successively formed on the substrate, and the third conductive plug 700 is formed in the substrate. The formation of the third conductive plug 700 may include the steps detailed below.

At first, a plastic encapsulation layer is formed on the surface of the substrate 100. In this embodiment, the plastic encapsulation layer is made up of the aforementioned first plastic encapsulation layer 710.

Next, the plastic encapsulation layer is etched so that a through hole is formed therein. In this embodiment, the first plastic encapsulation layer 710 is etched, and the extension of the top electrode 530 is exposed in the resulting through hole. A conductive material is then filled in the through hole, resulting in the formation of the third conductive plug, which is exposed at the top from the surface of the first plastic encapsulation layer 710.

Specifically, the third conductive plug 700 is connected to the extension of the top electrode 530. As a result, the top electrode 530 is electrically connected to the second interconnect via the third conductive plug 700 and the rewiring layer 230.

Afterward, referring to FIG. 3d, the substrate 600 is bonded to the back side of the device wafer so that the lower cavity 120 is positioned on the side of the piezoelectric crystal 520 away from the upper cavity 610. Accordingly, the bottom electrode 510 on the device wafer 100 is located on the side of the piezoelectric crystal 520 away from the top electrode 530.

In this embodiment, the bonding of the substrate 600 to the device wafer 100 may include: applying an adhesive layer to the substrate 600 in such a manner that the surface of the piezoelectric crystal 520 is exposed from the adhesive layer; and then bonding the device wafer and the substrate together by means of the adhesive layer.

Specifically, the bonding of the substrate 600 to the device wafer 100 may bring the rewiring layer 230 on the device wafer 100 that is connected to the second conductive plug into electrical contact with the third conductive plug 700 on the substrate 600 that is connected to the top electrode 530, achieving electrical connection of the top electrode 530 to the control circuit.

A crystal resonator corresponding to the above method according to an embodiment will be described below with reference to FIG. 2j. The crystal resonator includes:

a device wafer 100, the control circuit and a lower cavity 120 are formed in the device wafer 100, the lower cavity 120 having an opening at a back side of the device wafer, the control circuit optionally including interconnects, at least some of which extend to a front side of the device wafer 100;

a substrate 600, which is bonded to the device wafer 100 from the back side of the device wafer 100, and an upper cavity 610 is formed in the substrate 600, the upper cavity 610 having an opening facing the device wafer 100 and opposing the opening of the lower cavity 120;

a piezoelectric vibrator 500 comprising a bottom electrode 510, a piezoelectric crystal 520 and a top electrode 530, the piezoelectric vibrator 500 arranged between the device wafer 100 and the substrate 600 so that the lower and upper cavities 120, 610 are on opposing sides of the piezoelectric vibrator 500; and

a connecting structure electrically connecting both the bottom and top electrodes 510, 530 of the piezoelectric vibrator to the control circuit.

The lower cavity 120 in the device wafer 100 and the upper cavity 610 in the substrate 600 may be formed using planar fabrication processes, and the device wafer 100 and substrate 600 may be bonded together so that the upper and lower cavities 120, 610 are aligned with each other on opposing sides of the piezoelectric vibrator 500. In this way, the piezoelectric vibrator 500 and the control circuit can be integrated on the same device wafer so that the control circuit can cause the piezoelectric vibrator 500 to oscillate within the upper and lower cavities 610, 120. This helps in on-chip modulation under the control of the control circuit 110 for correcting raw deviations of the crystal resonator such as temperature and frequency drifts. Moreover, the crystal resonator fabricating using semiconductor processes is more compact in size and thus less power-consuming. Further, the piezoelectric vibrator 500 is allowed to be arranged, and brought into electrical connection with the control circuit, on the back side of the device wafer. This allows improved fabrication flexibility for the crystal resonator.

In this embodiment, the control circuit may include first and second circuits 111, 112, which are electrically connected to the top and bottom electrodes of the piezoelectric vibrator 500, respectively. The first circuit 111 may include a first transistor 111T and a first interconnect 111C. The first transistor 111T may be buried within the device wafer 100, and the first interconnect 111C may be connected to the first transistor 111T and extend to the front side of the device wafer 100. The second circuit 112 may include a second transistor 112T and a second interconnect 112C. The second transistor 112T may be buried within the device wafer 100, and the second interconnect 112C may be connected to the second transistor 112T and extend to the front side of the device wafer 100.

The connecting structure may include a first connection and a second connection. The first connection may be connected to the first interconnect 111C and the bottom electrode 510 of the piezoelectric vibrator. The second connection may be connected to the second interconnect 112C and the top electrode 530 of the piezoelectric vibrator.

The first connection may include a first conductive plug 221, the first conductive plug 221 penetrates through the device wafer 100 so as to extend to the front side of the device wafer into electrical connection with the first interconnect at one end and to extend to the back side of the device wafer 100 into electrical connection with the bottom electrode 510 of the piezoelectric vibrator at the other end.

The first connection may further include a first connecting wire 211. In this embodiment, the first connecting wire 211 is formed on the front side of the device wafer 100 so as to cover the first conductive plug 221 and come into electrical connection with the first interconnect. In alternative embodiments, the first connecting wire 211 may be formed on the back side of the device wafer 100 and connect the first conductive plug to the bottom electrode.

With this arrangement, the first connecting wire 211 and the first conductive plug 221 collaboratively lead a connection port of the first interconnect 111a from the front side of the device wafer 100 to the back side thereof. In this way, the connection port is allowed to be electrically connected to the bottom electrode of the piezoelectric vibrator 500 that is formed on the back side of the device wafer 100.

The second connection may include a second conductive plug 222, the second conductive plug 222 penetrates through the device wafer 100 so as to extend to the front side of the device wafer 100 into electrical connection with the second interconnect at one end and to extend to the back side of the device wafer 100 into electrical connection with the top electrode 530 of the piezoelectric vibrator at the other end.

The second connection may further include a second connecting wire 212. In this embodiment, the second connecting wire 212 is formed on the front side of the device wafer 100 so as to cover the second conductive plug 222 and thus come into electrical connection with the second interconnect. In alternative embodiments, the second connecting wire 212 may be formed on the back side of the device wafer 100 and connect the second conductive plug to the top electrode.

Likewise, the second connecting wire 212 and the second conductive plug 222 collaboratively lead a connection port of the second interconnect 112a from the front to back side of the device wafer 100. Thus, the connection port is allowed to be electrically connected to the top electrode of the piezoelectric vibrator 500 that is formed on the back side of the device wafer 100.

With continued reference to FIG. 2j, the crystal resonator may further include a planarized layer 300, which is formed over the front side of the device wafer 100 and has a surface facing away from the device wafer 100 that is not lower than a surface of the rewiring layer facing away from the device wafer.

In this embodiment, the bottom electrode 510 is formed on the back side of the device wafer 100 around the lower cavity 120 and has an extension that laterally extends beyond the piezoelectric crystal 520 over the first conductive plug 221, thus coming into electrical connection with the first conductive plug 221. The top electrode 530 also has an extension laterally extending beyond the piezoelectric crystal 520.

The top electrode 530 is formed around the upper cavity 610, the top electrode also extends laterally from the piezoelectric crystal 520 to form an extension, and the extension of the top electrode 530 is electrically connected to the second conductive plug 222 in the second connection via a third conductive plug in the second connection.

The third conductive plug 700 in the second connection may be formed on the back side of the device wafer 100, and the third conductive plug 700 is electrically connected to the top electrode 530 at one end and to the second conductive plug 222 at the other end.

Specifically, a plastic encapsulation layer may be arranged between the device wafer 100 and the substrate 600 such as to cover side surfaces of the piezoelectric crystal 520 and the extension of the top electrode. The third conductive plug 700 may be formed in the plastic encapsulation layer and connected to the extension of the top electrode at one end and to the second conductive plug 222 at the other end, thus bringing the top electrode 530 into electrical connection with the second circuit 112.

In one particular embodiment, the plastic encapsulation layer includes a first plastic encapsulation layer 710 and a second plastic encapsulation layer 720, which are stacked together in such a manner that the first plastic encapsulation layer 710 is closer to the substrate 600 than the second plastic encapsulation layer 720. A surface of the first plastic encapsulation layer 710 facing the device wafer 100 is flush with a surface of the piezoelectric crystal 520 facing the device wafer 100, and a surface of the second plastic encapsulation layer 720 facing the device wafer 100 is flush with a surface of the bottom electrode 510 facing the device wafer 100.

As shown in FIG. 2j, the third conductive plug 700 may extend through the first and second plastic encapsulation layers 710, 720. In this case, as a result of the bonding of the substrate 600 to the device wafer 100, the third conductive plug 700 extending up to the surface of the device wafer 100 may be connected to the extension of the top electrode at one end and to the second conductive plug 222 at the other end.

In alternative embodiments, in addition to the second conductive plug 222, the second connecting wire 212 and the third conductive plug, the second connection may further include an interconnecting wire. In such embodiments, the third conductive plug may be formed on the back side of the device wafer and connected to the second conductive plug 222 at the bottom. The interconnecting wire may cover at least part of the top electrode 530 at one end and cover the third conductive plug at the other end, thus coming into connection with the third conductive plug.

In alternative embodiments, the second connection may further include a rewiring layer, which is formed on the back side of the device wafer 100 and electrically connected to the control circuit. In such cases, the third conductive plug may be electrically connected to the top electrode at one end and extend up to, and come into electrical connection with, the rewiring layer at the other end.

With continued reference to FIG. 2j, in this embodiment, the device wafer 100 includes a substrate wafer and a dielectric layer 100B. The first and second transistors 111T, 112T may be both formed on the substrate wafer, and the dielectric layer 100B may reside on the substrate wafer and thus cover both the first and second transistors 111T, 112T. The first and second interconnects 111C, 112C may be all formed in the dielectric layer 100B.

In this embodiment, the lower cavity 120 extends through the device wafer and thus has another opening at the front side of the device wafer. Accordingly, a cap substrate may be optionally bonded to the front side of the device wafer to close the opening of the lower cavity present at the front side of the device wafer. The cap substrate may be composed of, for example, a silicon wafer.

In summary, in the proposed method, integration of the control circuit with the crystal resonator is achieved by employing planar fabrication processes to form the lower cavity in the device wafer containing the control circuit and the upper cavity in the substrate and then bonding the substrate to the back side of the device wafer to allow the piezoelectric vibrator to be brought into electrical connection with the control circuit on the same back side. Obviously, compared with traditional crystal resonators (e.g., surface-mount ones), the proposed crystal resonator fabricated using planar fabrication processes is more compact in size and hence less power-consuming. Moreover, it is able to integrate with other semiconductor components more easily with a higher degree of integration. Further, forming the piezoelectric vibrator from the back side of the device wafer allows higher process flexibility for the crystal resonator.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer having the control circuit formed therein;
forming a lower cavity in the device wafer, the lower cavity having an opening formed at a back side of the device wafer;
providing a substrate and etching the substrate so that an upper cavity of the crystal resonator is formed therein at a location corresponding to the lower cavity;
forming a piezoelectric vibrator comprising a top electrode, a piezoelectric crystal and a bottom electrode, the top electrode, the piezoelectric crystal and the bottom electrode being formed either on the back side of the device wafer or on the substrate;
forming a connecting structure on the device wafer or on the substrate; and
bonding the substrate to the back side of the device wafer such that the piezoelectric vibrator is situated between the device wafer and the substrate, with the upper and lower cavities being located on two sides of the piezoelectric vibrator, and electrically connecting both the top and bottom electrodes of the piezoelectric vibrator to the control circuit through the connecting structure.

2. The method for integrating a crystal resonator with a control circuit of claim 1, wherein the piezoelectric vibrator is formed on the back side of the device wafer or on the substrate, or wherein the bottom electrode of the piezoelectric vibrator is formed on the back side of the device wafer, and the top electrode and the piezoelectric crystal of the piezoelectric vibrator are sequentially formed on the substrate, or wherein the bottom electrode and the piezoelectric crystal of the piezoelectric vibrator are sequentially formed on the back side of the device wafer and the top electrode of the piezoelectric vibrator is formed on the substrate.

3. The method for integrating a crystal resonator with a control circuit of claim 1, wherein the upper cavity has a greater size than the piezoelectric crystal, and the substrate is bonded to the device wafer so that at least part of the piezoelectric crystal is located inside the upper cavity, or wherein
the upper cavity has a smaller size than the piezoelectric crystal, and the substrate is bonded to the device wafer so that the piezoelectric crystal covers and closes an opening of the upper cavity with peripheral edge portions of the piezoelectric crystal resting on a surface of the substrate.

4. The method for integrating a crystal resonator with a control circuit of claim 2, wherein forming the piezoelectric vibrator on the device wafer comprises:
forming the bottom electrode at a predetermined position on the back side of the device wafer;
bonding the piezoelectric crystal to the bottom electrode; and
forming the top electrode on the piezoelectric crystal, or comprises:
forming the top and bottom electrodes of the piezoelectric vibrator on the piezoelectric crystal; and bonding the top and bottom electrodes and the piezoelectric crystal as a whole to the back side of the device wafer, or
wherein forming the piezoelectric vibrator on the substrate comprises:
forming the top electrode at a predetermined position on a surface of the substrate;
bonding the piezoelectric crystal to the top electrode; and
forming the bottom electrode on the piezoelectric crystal, or comprises:
forming the top and bottom electrodes of the piezoelectric vibrator on the piezoelectric crystal; and bonding the top and bottom electrodes and the piezoelectric crystal as a whole to the substrate.

5-6. (canceled)

7. The method for integrating a crystal resonator with a control circuit of claim 2, wherein the top electrode is formed on the substrate and the bottom electrode is formed on the device wafer, wherein each of the top and bottom electrodes is formed using a vapor deposition process or a thin-film deposition process, and wherein the piezoelectric crystal is bonded to the top or bottom electrode.

8. The method for integrating a crystal resonator with a control circuit of claim 1, wherein the control circuit comprises a first interconnect and a second interconnect and the connecting structure comprises a first connection and a second connection,
the first connection connecting the first interconnect to the bottom electrode of the piezoelectric vibrator, the second connection connecting the second interconnect to the top electrode of the piezoelectric vibrator, and
wherein: the first connection comprises a first conductive plug in the device wafer, two ends of the first conductive plug electrically connected respectively to the first interconnect and the bottom electrode; or
the first connection comprises a first conductive plug in the device wafer and a first connecting wire on the back side of the device wafer, the first connecting wire electrically connected to one end of the first conductive plug, the first conductive plug electrically connected at the other end to the first interconnect, the first connecting wire electrically connected to the bottom electrode; or
the first connection comprises a first conductive plug in the device wafer and a first connecting wire on the front side of the device wafer, the first connecting wire electrically connected to one end of the first conductive plug, the first conductive plug electrically connected at the other end to the bottom electrode, the first connecting wire electrically connected to the first interconnect.

9. (canceled)

10. The method for integrating a crystal resonator with a control circuit of claim 8, wherein the formation of the first connection comprising the first conductive plug and the first connecting wire on the front side of the device wafer comprises:
forming a first connecting hole by etching the device wafer from the front side of the device wafer;
filling a conductive material in the first connecting hole, thus resulting in the formation of the first conductive plug;
forming the first connecting wire on the front side of the device wafer, the first connecting wire connecting the first conductive plug to the first interconnect; and
thinning the device wafer from the back side of the device wafer so that the first conductive plug is exposed and is available for electrical connection to the bottom electrode of the piezoelectric vibrator, or wherein
the formation of the first connection comprising the first conductive plug and the first connecting wire on the front side of the device wafer comprises:
forming the first connecting wire on the front side of the device wafer, the first connecting wire electrically connected to the first interconnect;
thinning the device wafer from the back side of the device wafer and forming a first connecting hole by etching the device wafer from the back side of the device wafer, the first connecting hole extending through the device wafer so that the first connecting wire is exposed in the first connecting hole; and
filling a conductive material in the first connecting hole, thus resulting in the formation of the first conductive plug, the first conductive plug connected at one end to the first connecting wire, the other end of the first conductive plug available for electrical connection to the bottom electrode of the piezoelectric vibrator, or wherein
the formation of the first connection comprising the first conductive plug and the first connecting wire on the back side of the device wafer comprises:
forming a first connecting hole by etching the device wafer from the front side of the device wafer;
filling a conductive material in the first connecting hole, thus resulting in the formation of the first conductive plug, the first conductive plug electrically connected to the first interconnect;
thinning the device wafer from the back side of the device wafer so that the first conductive plug is exposed; and
forming the first connecting wire on the back side of the device wafer, the first connecting wire connected at one end to the first conductive plug, the other end of the first connecting wire available for electrical connection to the bottom electrode, or wherein
the formation of the first connection comprising the first conductive plug and the first connecting wire on the back side of the device wafer comprises:
thinning the device wafer from the back side of the device wafer and forming a first connecting hole by etching the device wafer from the back side of the device wafer,
filling a conductive material in the first connecting hole, thus resulting in the formation of the first conductive plug, the first conductive plug electrically connected at one end to the first interconnect; and
forming the first connecting wire on the back side of the device wafer, the first connecting wire connected at one end to the other end of the first conductive plug, the other end of the first connecting wire available for electrical connection to the bottom electrode, or wherein
subsequent to the bonding of the substrate to the device wafer, the bottom electrode resides on the back side of the device wafer and extends beyond the piezoelectric crystal to come into electrical connection with the first conductive plug.

11-12. (canceled)

13. The method for integrating a crystal resonator with a control circuit of claim 8, wherein the second connection is formed prior to the formation of the top electrode, and wherein:
the second connection comprises a second conductive plug in the device wafer, two ends of the second conductive plug electrically connected respectively to the second interconnect and the top electrode; or
the second connection comprises a second conductive plug in the device wafer and a second connecting wire on the back side of the device wafer, the second connecting wire electrically connected to one end of the second conductive plug, the second conductive plug electrically connected at the other end to the second interconnect, the second connecting wire electrically connected to the top electrode; or
the second connection comprises a second conductive plug in the device wafer and a second connecting wire on the front side of the device wafer, the second connecting wire electrically connected to one end of the second conductive plug, the second conductive plug electrically connected at the other end to the top electrode, the second connecting wire electrically connected to the second interconnect.

14. The method for integrating a crystal resonator with a control circuit of claim 13, wherein the formation of the second connection comprising the second conductive plug and the second connecting wire on the front side of the device wafer comprises:
forming a second connecting hole by etching the device wafer from the front side of the device wafer;
filling a conductive material in the second connecting hole, thus resulting in the formation of the second conductive plug;
forming the second connecting wire on the front side of the device wafer, the second connecting wire connecting the second conductive plug to the second interconnect; and
thinning the device wafer from the back side of the device wafer so that the second conductive plug is exposed and becomes available for electrical connection to the top electrode of the piezoelectric vibrator, or wherein
the formation of the second connection comprising the second conductive plug and the second connecting wire on the front side of the device wafer comprises:
forming the second connecting wire on the front side of the device wafer, the second connecting wire electrically connected to the second interconnect;
thinning the device wafer from the back side of the device wafer and forming a second connecting hole by etching the device wafer from the back side thereof, the second connecting hole extending through the device wafer so that the second connecting wire is exposed in the second connecting hole; and
filling a conductive material in the second connecting hole, thus resulting in the formation of the second conductive plug, the second conductive plug connected at one end to the second connecting wire, the other end of the second conductive plug available for electrical connection to the top electrode of the piezoelectric vibrator, or wherein
the formation of the second connection comprising the second conductive plug and the second connecting wire on the back side of the device wafer comprises:
forming a second connecting hole by etching the device wafer from the front side of the device wafer;
filling a conductive material in the second connecting hole, thus resulting in the formation of the second conductive plug, the second conductive plug electrically connected to the second interconnect;
thinning the device wafer from the back side of the device wafer so that the second conductive plug is exposed; and
forming the second connecting wire on the back side of the device wafer, the second connecting wire connected at one end to the second conductive plug, the other end of the second connecting wire available for electrical connection to the top electrode, or wherein
the formation of the second connection comprising the second conductive plug and the second connecting wire on the back side of the device wafer comprises:
thinning the device wafer from the back side of the device wafer and forming a second connecting hole by etching the device wafer from the back side of the device wafer,
filling a conductive material in the second connecting hole, thus resulting in the formation of the second conductive plug, the second conductive plug electrically connected at one end to the second interconnect; and
forming the second connecting wire on the back side of the device wafer, the second connecting wire connected at one end to the other end of the second conductive plug, the other end of the second connecting wire available for electrical connection to the top electrode.

15. (canceled)

16. The method for integrating a crystal resonator with a control circuit of claim 13, wherein the piezoelectric crystal is formed on the back side of the device wafer, and the formation of the second connection further comprises, prior to the formation of the top electrode on the device wafer:
forming a plastic encapsulation layer on the back side of the device wafer; and
forming a through hole in the plastic encapsulation layer and filling a conductive material in the through hole, thus resulting in the formation of a third conductive plug, the third conductive plug has a bottom electrically connected to the second conductive plug, the third conductive plug has a top exposed from the plastic encapsulation layer, and
wherein the top electrode is formed on the device wafer so that the top electrode extends beyond the piezoelectric crystal over the top of the third conductive plug, thus coming into electrical connection with the third conductive plug; or subsequent to the formation of the top electrode, an interconnecting wire is formed on the plastic encapsulation layer, the interconnecting wire extending over the top electrode at one end and over the third conductive plug at the other end, or wherein
the top electrode and the piezoelectric crystal are successively formed on the substrate, wherein the formation of the second connection further comprises, prior to the bonding of the substrate to the device wafer:
forming a plastic encapsulation layer on the surface of the substrate;
forming a through hole in the plastic encapsulation layer, the top electrode being exposed in the through hole; and
filling a conductive material in the through hole, thus resulting in the formation of a third conductive plug, the third conductive plug electrically connected at one end to the top electrode, and
wherein the device wafer and the substrate are bonded together so that the third conductive plug is brought into electrical connection with the second conductive plug at the other end.

17. (canceled)

18. The method for integrating a crystal resonator with a control circuit of claim 8, wherein the control circuit further comprises a first transistor and a second transistor, the first transistor being connected to the first interconnect and the second transistor being connected to the second interconnect.

19. The method for integrating a crystal resonator with a control circuit of claim 1, wherein the device wafer comprises a substrate wafer and a dielectric layer formed on the substrate wafer, and wherein the substrate wafer is a silicon-on-insulator substrate comprising a base layer, a buried oxide layer and a top silicon layer stacked in sequence from the back side to the front side.

20. (canceled)

21. The method for integrating a crystal resonator with a control circuit of claim 1, wherein the formation of the lower cavity comprises: etching the device wafer from the front side of the device wafer, thereby resulting in the formation of the lower cavity of the crystal resonator; thinning the device wafer from the back side of the device wafer, thereby exposing the lower cavity; and bonding a cap substrate to the front side of the device wafer so that the cap substrate covers and closes the opening of the lower cavity at the front side of the device wafer, or
wherein the formation of the lower cavity comprises etching the device wafer from the back side of the device wafer, thereby resulting in the formation of the lower cavity of the crystal resonator,
and/or
wherein the device wafer comprises a silicon-on-insulator substrate comprising a base layer, a buried oxide layer and a top silicon layer stacked in sequence from the back side to the front side, and
wherein the method further comprises, prior to forming the lower cavity by etching the device wafer from the back side of the device wafer, removing the base layer and the buried oxide layer, and forming the lower cavity by etching the device wafer from the back side of the device wafer comprises forming the lower cavity by etching the top silicon layer.

22. (canceled)

23. The method for integrating a crystal resonator with a control circuit of claim 1, wherein the bonding of the device wafer and the substrate comprises:
applying an adhesive layer to the back side of the device wafer and/or the substrate and bonding the device wafer and the substrate together by means of the adhesive layer, or wherein
the top electrode and the piezoelectric crystal of the piezoelectric vibrator are successively formed on the substrate, and wherein
the bonding comprising:
applying an adhesive layer to the substrate so that a surface of the piezoelectric crystal is exposed from the adhesive layer; and
bonding the device wafer and the substrate together by means of the adhesive layer, or wherein
the bottom electrode and the piezoelectric crystal of the piezoelectric vibrator are successively formed on the back side of the device wafer, and wherein
the bonding comprising:
applying an adhesive layer to the back side of the device wafer so that a surface of the piezoelectric crystal is exposed from the adhesive layer; and
bonding the device wafer and the substrate together by means of the adhesive layer.

24-25. (canceled)

26. The method for integrating a crystal resonator with a control circuit of claim 1, wherein the piezoelectric crystal is a quartz crystal plate, or
wherein on each of the device wafer and the substrate, there are defined a plurality of device areas, in each of which a crystal resonator is formed.

27. (canceled)

28. A structure for integrating a crystal resonator with a control circuit, comprising:
a device wafer in which the control circuit and a lower cavity are formed, the lower cavity having an opening at a back side of the device wafer;
a substrate, which is bonded to the device wafer from the back side of the device wafer, and in which an upper cavity is formed, the upper cavity having an opening arranged in opposition to the opening of the lower cavity;
a piezoelectric vibrator comprising a bottom electrode, a piezoelectric crystal and a top electrode, the piezoelectric vibrator arranged between the device wafer and the substrate so that the lower and upper cavities are on opposing sides of the piezoelectric vibrator; and
a connecting structure electrically connecting both the top and bottom electrodes of the piezoelectric vibrator to the control circuit.

29. The structure for integrating a crystal resonator with a control circuit of claim 28, wherein the control circuit comprises a first interconnect and a second interconnect and the connecting structure comprises a first connection and a second connection,
the first connection connecting the first interconnect to the bottom electrode of the piezoelectric vibrator, the second connection connecting the second interconnect to the top electrode of the piezoelectric vibrator, and
wherein the first connection comprises
a first conductive plug, which extends through the device wafer so that one end of the first conductive plug is located at the front side of the device wafer and electrically connected to the first interconnect and the other end of the first conductive plug is located at the back side of the device wafer and electrically connected to the bottom electrode of the piezoelectric vibrator;
a first connecting wire,
and wherein: the first connecting wire is formed on the front side of the device wafer and connects the first conductive plug to the first interconnect, or
the first connecting wire is formed on the back side of the device wafer and connects the first conductive plug to the bottom electrode.

30-31. (canceled)

32. The structure for integrating a crystal resonator with a control circuit of claim 29, wherein the bottom electrode is formed on the back side of the device wafer so as to extend beyond the piezoelectric crystal and come into electrical connection with the first conductive plug.

33. The structure for integrating a crystal resonator with a control circuit of claim 29, wherein the second connection comprises
a second conductive plug, which extends through the device wafer so that one end of the second conductive plug is located at the front side of the device wafer and the other end of the second conductive plug is located at the back side of the device wafer and electrically connected to the top electrode of the piezoelectric vibrator, and
wherein the second connection further comprises a second connecting wire, and wherein:
the second connecting wire is formed on the front side of the device wafer and connects the second conductive plug to the second interconnect, or
the second connecting wire is formed on the back side of the device wafer and connects the second conductive plug to the top electrode, and wherein
the second connection further comprises
a third conductive plug formed on the back side of the device wafer, the third conductive plug electrically connected to the top electrode at one end and to the second conductive plug at the other end,
or
wherein the second connection further comprises:
an interconnecting wire, which is formed on the back side of the device wafer and is electrically connected to the second conductive plug; and
a third conductive plug formed on the back side of the device wafer, the third conductive plug electrically connected to the top electrode at one end and to the interconnecting wire at the other end.

34-36. (canceled)

37. The structure for integrating a crystal resonator with a control circuit of claim 29, wherein the control circuit further comprises a first transistor connected to the first interconnect and a second transistor connected to the second interconnect.
